(19) United States
(12) Patent Application Publication
(10) Pub. No.: US 2006/0113670 A1
(43) Pub. Date: Jun. 1, 2006

(54) Multi-layer wiring, method of manufacturing the same and thin film transistor having the same

(75) Inventors: Je-Hun Lee, Seoul (KR); Beom-Seok Cho, Seoul (KR); Chang-Oh Jeong, Suwon-si (KR); Yang-Ho Bae, Suwon-si (KR)

Correspondence Address: David W. Heid;MacPHERSON KWOK CHEN & HEID LLP, 1762 Technology Drive, Suite 226, San Jose, CA, 95110, US

(73) Assignee: SAMSUNG ELECTRONICS CO., LTD., Suwon-si (KR)

(21) Appl. No.: 11/221,492

(22) Filed: Sep. 7, 2005

(30) Foreign Application Priority Data
Nov. 29, 2004 (KR) 2004-98689

(51) Int. Cl. H01L 23/52

(52) U.S. Cl. 257/758

(57) ABSTRACT

A multi-layer wiring for use with thin film transistors (TFTs), methods of manufacturing the multi-layer wiring, and TFTs employing the multi-layer wiring are provided. In one embodiment, the multi-layer wiring includes a main wiring and a sub-wiring on the main wiring. The main wiring includes a first metal and the sub-wiring includes an alloy wherein a majority of the alloy is the first metal. The multi-layer wiring can exhibit decreased electrical resistance and a reduced tendency to develop malfunctions such as hillocks or spiking. The multi-layer wiring can also exhibit improved contact characteristics with other conductive elements of TFT display devices.

### CROSS-REFERENCE TO RELATED APPLICATION

The present application claims priority to corresponding Korean Patent Application No. 2004-98689 filed in the Korean Intellectual Property Office, Republic of Korea, on Nov. 29, 2004, the disclosure of which is hereby incorporated by reference in its entirety.

### BACKGROUND OF THE INVENTION

1. Field of the Invention

The present invention relates to wiring for use with thin film transistors (TFTs). More particularly, the present invention relates to a multi-layer wiring for use with TFTs, methods of manufacturing the multi-layer wiring, and TFTs employing the multi-layer wiring.

2. Description of the Related Art

Flat display devices such as liquid crystal display (LCD) devices, organic light emitting display (OLED) devices, plasma display panel (PDP) devices, and other devices display images based on electric signals.

Such display devices can include TFTs and wiring electrically connected to the individual TFTs. By applying a driving signal to each TFT through the wiring, an image can be displayed.

The quality of the displayed image can be affected by electrical characteristics of the TFTs and the wiring. Unfortunately, the use of conventional aluminum wiring in such display devices can be problematic.

Specifically, at temperatures greater than about 150° C., hillocks or spiking may form on the wiring. Such aluminum wiring may also exhibit inferior contact characteristics with other conductive elements of the display devices.

### SUMMARY OF THE INVENTION

In one embodiment, the present invention provides a multi-layer wiring exhibiting improved contact characteristics and a reduced tendency to develop malfunctions in the form of hillocks or spiking.

In another embodiment, the present invention provides a method of manufacturing the above-mentioned multi-layer wiring.

In another embodiment, the present invention provides a thin film transistor (TFT) having the above-mentioned multi-layer wiring.

A multi-layer wiring in accordance with another embodiment of the present invention includes a main wiring and a sub-wiring. The main wiring includes a first metal. The sub-wiring is on the main wiring, and includes an alloy. A majority of the alloy is the first metal.

A multi-layer wiring in accordance with another embodiment of the present invention includes a main wiring and a sub-wiring. The main wiring includes a first metal. The sub-wiring is on a first surface of the main wiring, and includes an alloy to dissipate a thermal stress of the main wiring so as to prevent a deformation of the main wiring and improve contact characteristics. A majority of the alloy is the first metal.

In another embodiment, the alloy includes the first metal, a second metal for preventing a deformation of the main wiring, and a third metal for improving contact characteristics.

In yet another embodiment, the first metal includes aluminum, copper or silver. The second metal includes neodymium, titanium, magnesium, silicon, molybdenum or zirconium. The third metal includes nickel, scandium or zinc.

A method of manufacturing a multi-layer wiring in accordance with another embodiment of the present invention is provided as follows. A main thin film that includes a first metal is formed on a substrate. A sub-thin film is formed on an upper surface of the main thin film. The sub-thin film includes an alloy to dissipate a thermal stress of the main thin film so as to prevent a deformation of the main thin film and improve contact characteristics. A majority of the alloy is the first metal. The sub-thin film and the main thin film are partially etched to form a main wiring on the substrate and a sub-wiring on the main wiring.

A TFT in accordance with another embodiment of the present invention includes a gate line, an insulating layer, a channel layer, a data line and a drain electrode. The gate line is on a substrate and is electrically connected to a gate electrode. The gate line includes a main wiring and a sub-wiring. The main wiring includes a first metal. The sub-wiring is on a first surface of the main wiring. The sub-wiring includes an alloy to dissipate a thermal stress of the main wiring so as to prevent a deformation of the main wiring and improve contact characteristics. A majority of the alloy is the first metal. The insulating layer is on the substrate having the gate line and the gate electrode. The channel layer is on a portion of the insulating layer corresponding to the gate electrode. The data line is substantially perpendicular to the gate line on the insulating layer. The data line is electrically connected to a source electrode that is electrically connected to the channel layer. The drain electrode is electrically connected to the channel layer.

In another embodiment, the data line includes the main wiring, a sub-wiring and an auxiliary sub-wiring. The auxiliary sub-wiring is on a second surface of the main wiring to prevent a diffusion of the first metal.

According to various embodiments of the present invention, an electrical resistance of the wiring is decreased, and malfunctions such as hillocks or spiking are decreased. In various embodiments, contact characteristics between the wiring and other conductive elements are additionally improved.

### BRIEF DESCRIPTION OF THE DRAWINGS

The above and other advantages of the present invention, including exemplary embodiments thereof, will become apparent by referring to the following detailed description and the accompanying drawings, in which:

FIG. 1 is a plan view showing a multi-layer wiring in accordance with an exemplary embodiment of the present invention;

FIG. 2 is a cross-sectional view showing a sub-wiring shown in FIG. 1;

FIG. 3 is a plan view showing a pad member and a transparent conductive layer on an end portion of the multi-layer wiring shown in FIG. 1;

FIG. 4 is a cross-sectional view taken along a line I-I′ shown in FIG. 3;

FIG. 5 is a cross-sectional view showing a multi-layer wiring in accordance with another exemplary embodiment of the present invention;

FIG. 6 is a cross-sectional view showing a multi-layer wiring in accordance with another exemplary embodiment of the present invention;

FIG. 7 is a cross-sectional view showing a sub-thin film of the multi-layer wiring shown in FIG. 6;

FIG. 8 is a cross-sectional view showing a main wiring and a sub-wiring of the multi-layer wiring shown in FIG. 6;

FIG. 9 is a cross-sectional view showing an auxiliary sub-thin film on a substrate in accordance with another exemplary embodiment of the present invention;

FIG. 10 is a cross-sectional view showing a main thin film on the substrate shown in FIG. 9;

FIG. 11 is a cross-sectional view showing a sub-thin film on the substrate shown in FIG. 9;

FIG. 12 is a cross-sectional view showing a main wiring and a sub-wiring on the substrate shown in FIG. 9;

FIG. 13 is a plan view showing a thin film transistor (TFT) in accordance with another exemplary embodiment of the present invention;

FIG. 14 is a cross-sectional view taken along a line II-II′ shown in FIG. 13;

FIG. 15 is a cross-sectional view taken along a line III-III′ shown in FIG. 13;

FIG. 16 is a plan view showing a TFT in accordance with another exemplary embodiment of the present invention;

FIG. 17 is a cross-sectional view taken along a line IV-IV′ shown in FIG. 16; and

FIG. 18 is a cross-sectional view taken along a line V-V′ shown in FIG. 16.

### DETAILED DESCRIPTION OF THE EMBODIMENTS

The invention is described more fully hereinafter with reference to the accompanying drawings, in which embodiments of the invention are shown. The invention may, however, be embodied in many different forms and should not be construed as limited to the embodiments set forth herein. The embodiments are provided for purposes of example only, and not for purposes of limitation. In the drawings, the size and relative sizes of layers and regions may be exaggerated for clarity.

It will be understood that when an element or layer is referred to as being “on”, “connected to” or “coupled to” another element or layer, it can be directly on, connected, or coupled to the other element or layer, or intervening elements or layers may be present. In contrast, when an element is referred to as being “directly on,” “directly connected to,” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third, etc. may be used herein to describe various elements, components, regions, layers and/or sections, such elements, components, regions, layers and/or sections should not be limited by such terms. The terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be described in detail with reference to the accompanying drawings.

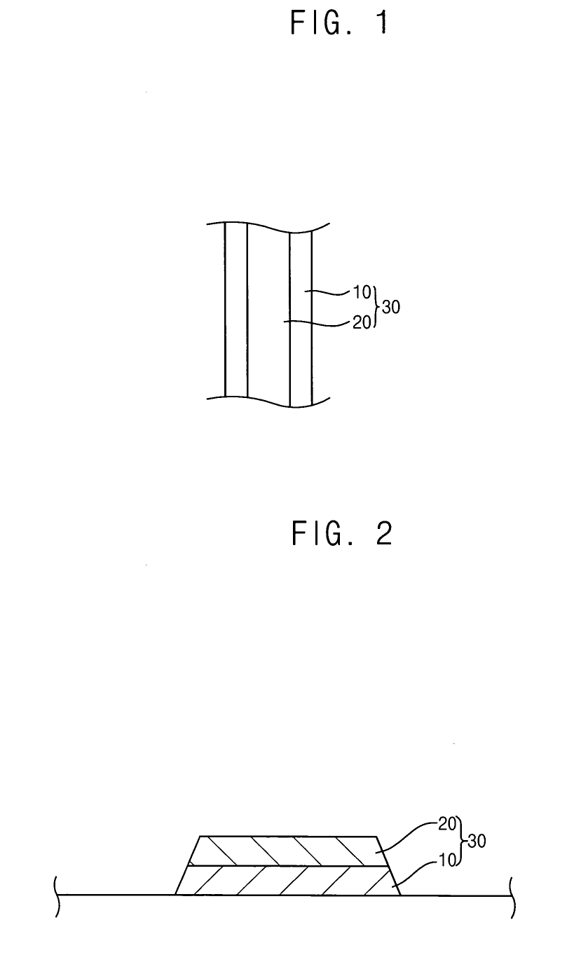

FIG. 1 is a plan view showing a multi-layer wiring in accordance with an exemplary embodiment of the present invention. FIG. 2 is a cross-sectional view showing a sub-wiring shown in FIG. 1.

Referring to FIGS. 1 and 2, a driving signal is applied to pixels of a display through a multi-layer wiring 30. In this exemplary embodiment, the multi-layer wiring 30 may be a gate wiring through which a gate turn-on signal is applied to a thin film transistor (TFT).

The multi-layer wiring 30 includes a main wiring 10 and a sub-wiring 20. The main wiring 10 is over a glass substrate, and the sub-wiring 20 is on the main wiring 10.

In order to prevent a voltage drop and a deformation of a driving signal, the main wiring 10 includes a first metal of low resistance, such as aluminum, copper, silver, etc. These can be used alone or in a combination thereof.

When the main wiring 10 includes copper, a diffusion preventing layer (not shown) that can include tin oxide, zinc oxide, etc., is interposed between the main wiring 10 and the sub-wiring 20 to prevent a diffusion of copper toward the sub-wiring 20.

When the main wiring 10 includes aluminum, a hillock or a spiking may be formed on the main wiring 10 at temperatures greater than about 150° C. The hillock is a fold-up structure formed by thermal stress compression. The spiking is a tension crack formed by thermal stress tension. In this exemplary embodiment, the main wiring 10 includes aluminum.

The sub-wiring 20 is etched by an etchant that etches the main wiring 10. In this exemplary embodiment, the sub-wiring 20 includes an alloy having the first metal so that the sub-wiring 20 is etched with the main wiring 10 by the same etchant. When the first metal of the main wiring 10 includes aluminum, the sub-wiring 20 includes an alloy having aluminum. Alternatively, when the first metal of the main wiring 10 includes copper, the sub-wiring 20 includes an alloy having copper. Similarly, when the first metal of the main wiring 10 includes silver, the sub-wiring 20 includes an alloy having silver.

In this exemplary embodiment, the sub-wiring 20 is etched with the main wiring 10 by the etchant so that sides of the main wiring 10 and the sub-wiring 20 are slanted relative to the main wiring 10 and the sub-wiring 20. The sub-wiring 20 may include the alloy having aluminum. In this exemplary embodiment, a majority of the alloy of the sub-wiring 20 is the first metal.

Referring to FIG. 2, the sub-wiring 20 dissipates a thermal stress of the main wiring 10 to prevent the formation of hillocks or spiking on the main wiring 10. The sub-wiring 20 includes a second metal. In this exemplary embodiment, the sub-wiring 20 includes an alloy having the second metal.

Examples of the second metal that can be used for the sub-wiring 20 include neodymium, niobium, titanium, magnesium, silicon, molybdenum, zirconium, an alloy thereof, etc. These can be used alone or in a combination thereof. In this exemplary embodiment, the second metal is neodymium. The alloy of the sub-wiring 20 includes the second metal in a range of about 0.01 atomic percent (“at %”) to about 5 at % with respect to the first metal.

The sub-wiring 20 further includes a third metal to improve contact characteristics of the sub-wiring 20. Examples of the third metal that can be used for the sub-wiring 20 include nickel, scandium, zinc, an alloy thereof, etc. These can be used alone or in a combination thereof. In this exemplary embodiment, the sub-wiring 20 includes an alloy having the third metal. The alloy of the sub-wiring 20 includes the third metal in a range of about 0.01 at % to about 5 at % with respect to the first metal. That is, the sub-wiring 20 includes the alloy having the first, second and third metals.

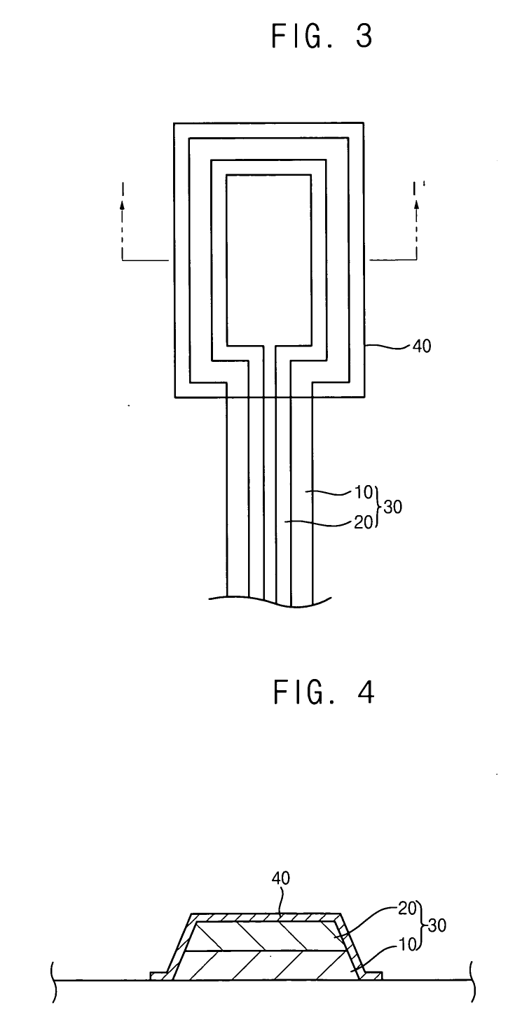

FIG. 3 is a plan view showing a pad member and a transparent conductive layer on an end portion of the multi-layer wiring shown in FIG. 1. FIG. 4 is a cross-sectional view taken along a line I-I′ shown in FIG. 3.

Referring to FIGS. 3 and 4, the sub-wiring 20 that includes the alloy of aluminum, neodymium and nickel has better contact characteristics with a conductive layer 40 than a sub-wiring that includes only one of aluminum, neodymium and nickel. The conductive layer 40 includes a transparent conductive material, such as indium zinc oxide (IZO), indium tin oxide (ITO), etc. For example, the contact resistance between the sub-wiring 20 including aluminum, neodymium and nickel, and the conductive layer 40 that includes IZO, is about 8.68×10⁵ Ω.

The main wiring 10 includes aluminum, and the sub-wiring 20 includes the alloy of aluminum, neodymium and nickel to decrease a galvanic corrosion on an interface between the main wiring 10 and the sub-wiring 20.

A difference between galvanic potentials of the indium tin oxide and aluminum in an aqueous solution of tetramethylammonium hydroxide (TMAH) is about −1.36 V. A difference between galvanic potentials of the indium tin oxide and the alloy of aluminum, neodymium and nickel is about −0.74 V. Accordingly, galvanic corrosion is decreased in embodiments where the sub-wiring 20 includes the alloy of aluminum, neodymium and nickel.

The sub-wiring 20 can be implemented with a thickness less than that of the main wiring 10. In one example, the thickness of the sub-wiring 20 is in a range of about 10 Å to about 5,000 Å.

In this exemplary embodiment, the main wiring 10 is etched with the sub-wiring 20 by the same etchant. In addition, the formation of hillocks and spiking on the main wiring 10 is decreased, and the contact characteristics are improved.

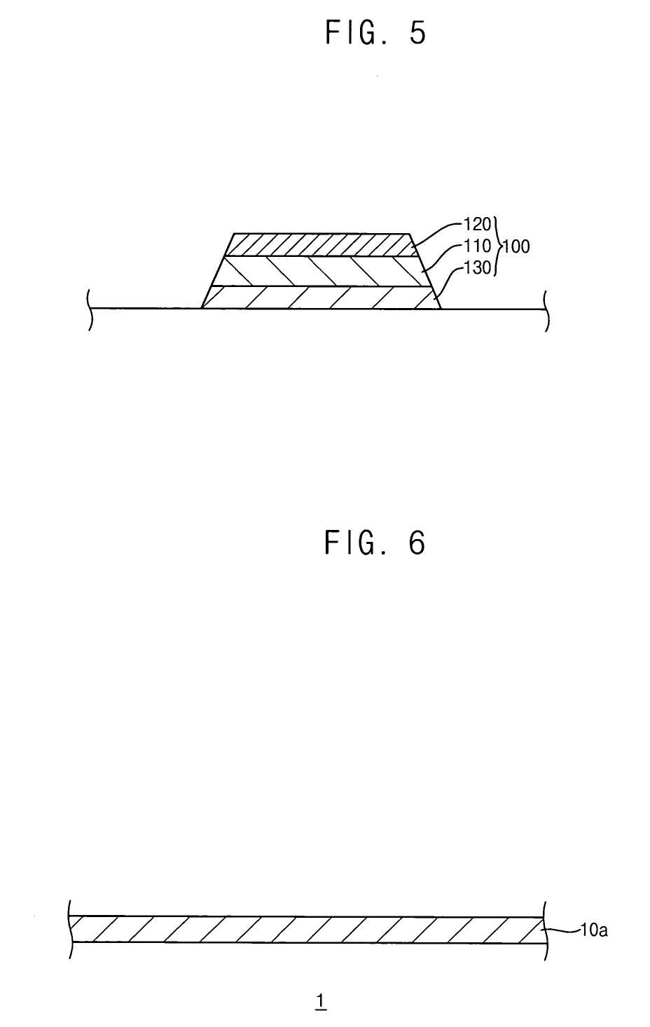

FIG. 5 is a cross-sectional view showing a multi-layer wiring in accordance with another exemplary embodiment of the present invention. It will be appreciated that the various features and advantages described above with respect to elements 10 and 20 of FIGS. 1 to 4 can be applied to elements 110 and 120, respectively, of FIG. 5.

Referring to FIG. 5, a driving signal is applied to pixels of a display through a multi-layer wiring 100. In this exemplary embodiment, the multi-layer wiring 100 may be a gate wiring through which a gate turn-on signal is applied to a TFT.

The multi-layer wiring 100 includes a main wiring 110, a sub-wiring 120 and an auxiliary sub-wiring 130. The main wiring 110 is over a glass substrate. The sub-wiring 120 is on the main wiring 110, and the auxiliary sub-wiring 130 is interposed between the main wiring 110 and the glass substrate.

The auxiliary sub-wiring 130 dissipates a thermal stress between the main wiring 110 and the substrate to prevent spiking. The auxiliary sub-wiring 130 includes a fourth metal. Examples of the fourth metal that can be used for the auxiliary sub-wiring 130 include molybdenum, tungsten-molybdenum, neodymium-molybdenum, titanium-molybdenum, titanium, tantalum, an alloy thereof, etc. These can be used alone or in a combination thereof.

In this exemplary embodiment, the main wiring 110, the sub-wiring 120 and the auxiliary sub-wiring 130 may be etched by the same etchant. The sub-wiring 120 and the auxiliary sub-wiring 130 prevent the formation of hillocks and spiking on the main wiring 110, and improve the contact characteristics of the multi-layer wiring.

FIGS. 6 to 8 show a process for forming a multi-layer wiring in accordance with another exemplary embodiment of the present invention. It will be appreciated that the various features and advantages described above with respect to elements 10 and 20 of FIGS. 1 to 4 can be applied to elements 10a and 20a, respectively, of FIGS. 6 to 8.

Referring to FIG. 6, a main thin film 10a can be formed on a substrate 1 through a chemical vapor deposition (CVD) method or a sputtering method. Alternatively, the main thin film 10a may be formed on a layer (not shown) that is on the substrate 1.

When the main thin film 10a includes copper, a diffusion preventing layer (not shown) that includes tin oxide, zinc oxide, etc., is interposed between the main thin film 10a and the substrate 1 to prevent a diffusion of copper toward the substrate 1. In this exemplary embodiment, the main thin film 10a includes aluminum.

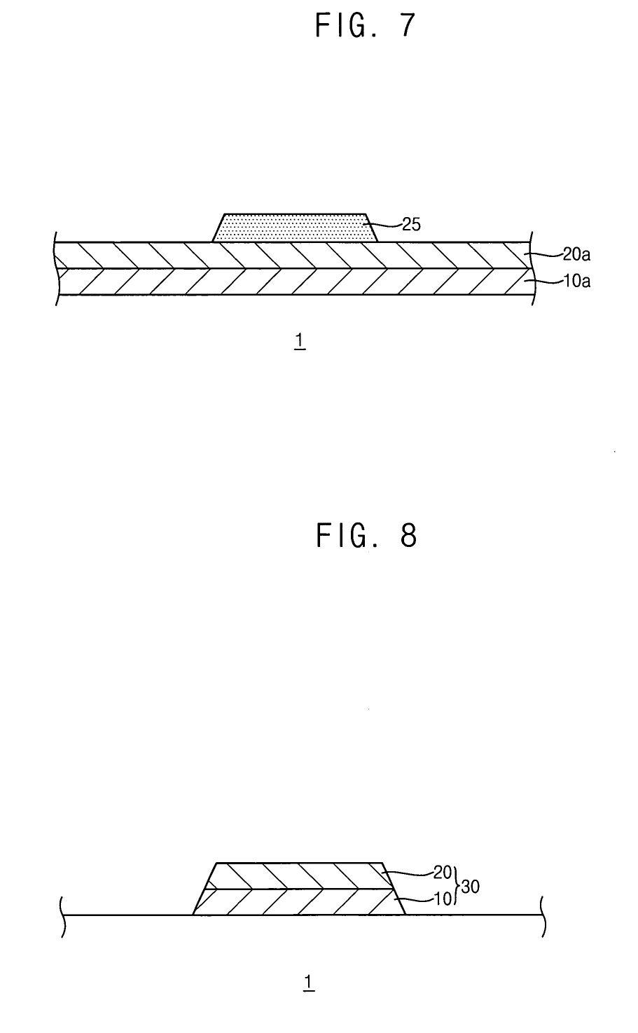

FIG. 7 is a cross-sectional view showing a sub-thin film of the multi-layer wiring shown in FIG. 6.

Referring to FIG. 7, a sub-thin film 20a is formed on the main thin film 10a to prevent a surface deformation of the main thin film 10a by thermal stress.

The sub-thin film 20a can be formed on the main thin film 10a through a CVD method or a sputtering method.

In this exemplary embodiment, the main thin film 10a includes aluminum, and the sub-thin film 20a includes the alloy having aluminum that is a majority of the alloy of the sub-thin film 20a.

The sub-thin film 20a dissipates the thermal stress of the main thin film 10a to prevent a deformation of the main thin film 10a. The sub-thin film 20a includes a second metal to prevent the deformation of the main thin film 10a.

Referring again to FIG. 7, a photoresist thin film (not shown) is formed on the sub-thin film 20a. The photoresist thin film (not shown) is partially removed to form a photoresist pattern 25 on the sub-thin film 20a.

FIG. 8 is a cross-sectional view showing a main wiring and a sub-wiring of the multi-layer wiring shown in FIG. 6.

Referring to FIG. 8, the main thin film 10a and the sub-thin film 20a are partially etched using the photoresist pattern 25 as an etching mask to form a multi-layer wiring 30 having a main wiring 10 and a sub-wiring 20 on the substrate 1.

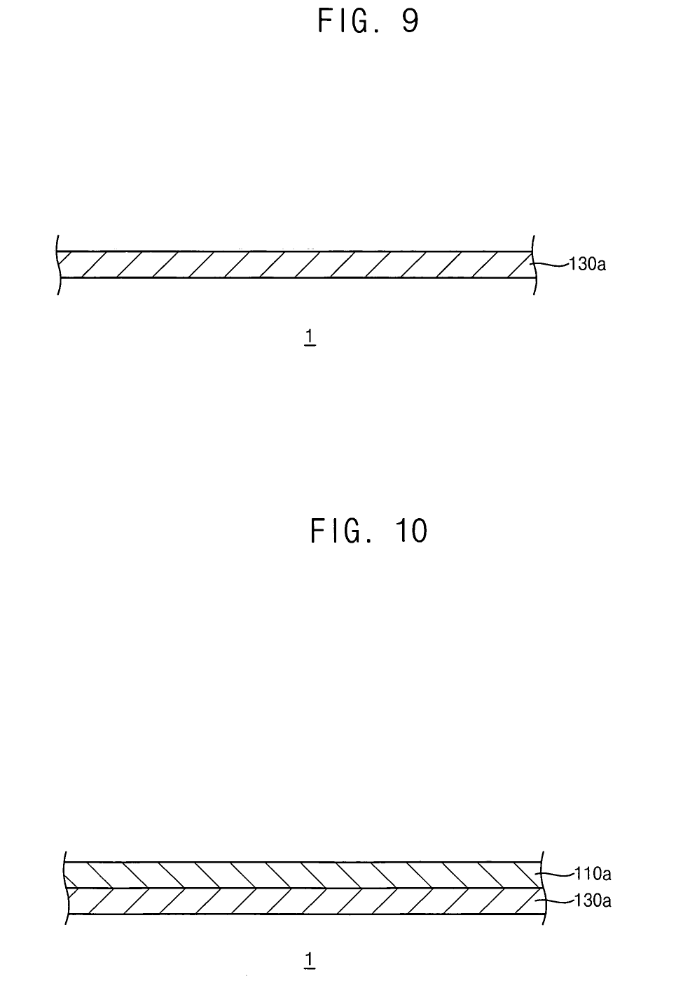

FIGS. 9 to 12 show a process of forming an auxiliary sub-thin film on a substrate in accordance with another exemplary embodiment of the present invention. It will be appreciated that the various features and advantages described above with respect to elements 10 and 20 of FIGS. 1 to 4 can be applied to elements 110a and 120a, respectively, of FIGS. 9 to 12. It will further be appreciated that the various features and advantages described above with respect to elements 10a and 20a of FIGS. 6 to 8 can be applied to elements 110a and 120a, respectively, of FIGS. 9 to 12.

Referring to FIG. 9, an auxiliary sub-thin film 130a is formed on a substrate 1.

In this exemplary embodiment, the auxiliary sub-thin film 130a can be formed on the substrate 1 through a CVD method or a sputtering method. Alternatively, the auxiliary sub-thin film 130a may be formed on a layer that is on the substrate 1.

Examples of a metal that can be used for the auxiliary sub-thin film 130a include molybdenum, tungsten-molybdenum, neodymium-molybdenum, titanium-molybdenum, titanium, tantalum, an alloy thereof, etc. These can be used alone or in a combination thereof.

FIG. 10 is a cross-sectional view showing a main thin film on the substrate shown in FIG. 9.

Referring to FIG. 10, a main thin film 110a is formed on the auxiliary sub-thin film 130a. In this exemplary embodiment, the main thin film 110a can be formed on the auxiliary sub-thin film 130a through a CVD method or a sputtering method.

Referring to FIG. 11, a sub-thin film 120a is formed on the main thin film 110a to prevent a deformation of the main thin film 110a by a thermal stress.

The sub-thin film 120a can be formed on the main thin film 110a through a CVD method or a sputtering method.

Referring again to FIG. 11, a photoresist thin film (not shown) is formed on the sub-thin film 120a. The photoresist thin film (not shown) is partially removed to form a photoresist pattern 125 on the sub-thin film 120a.

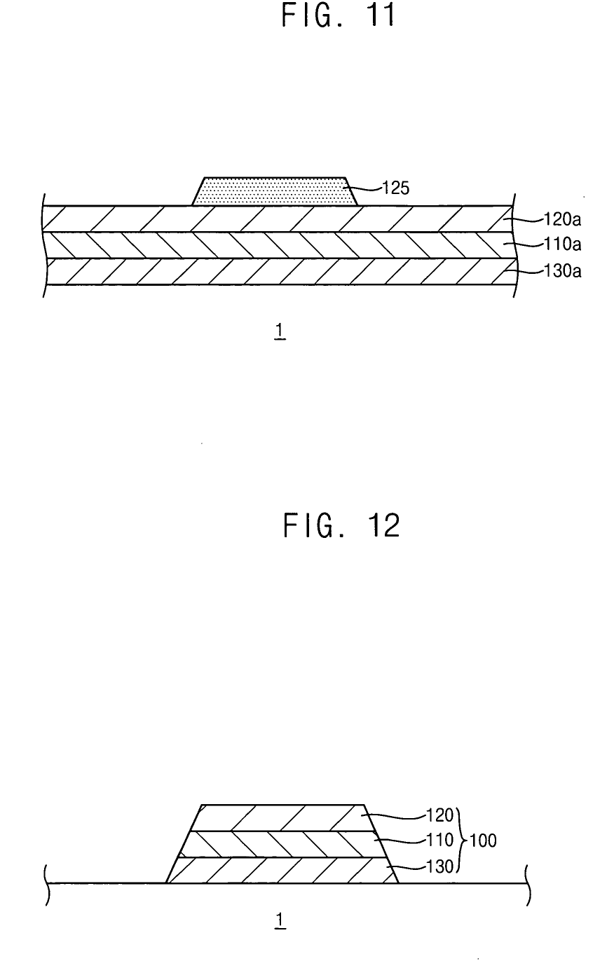

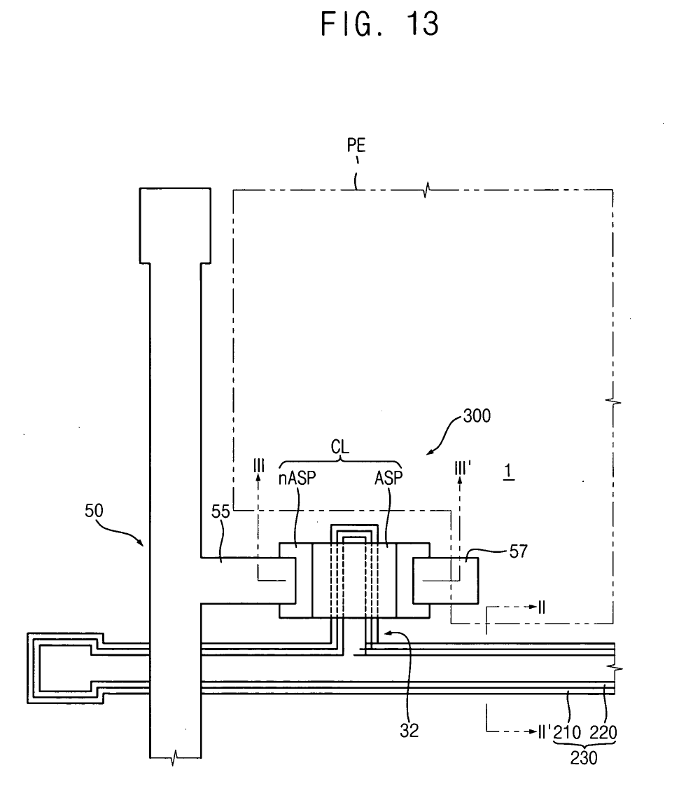

Referring to FIG. 12, the main thin film 110a, the sub-thin film 120a and the auxiliary sub-thin film 130a are partially etched using the photoresist pattern 125 as an etching mask to form a multi-layer wiring 100 having a main wiring 110, a sub-wiring 120 and an auxiliary sub-wiring 130 on the substrate 1.

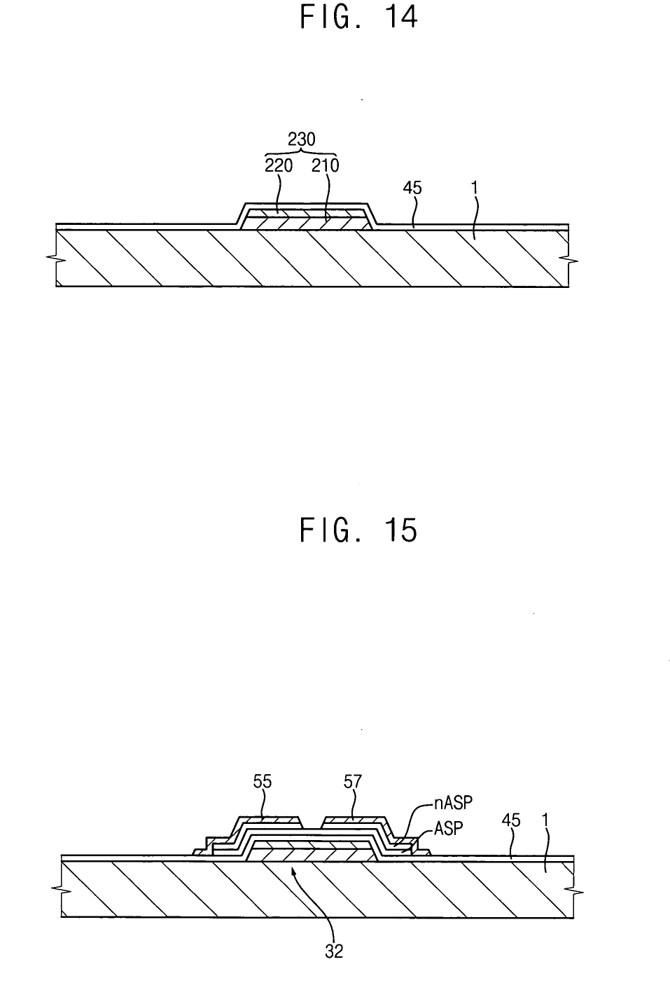

FIG. 13 is a plan view showing a thin film transistor (TFT) in accordance with another exemplary embodiment of the present invention. FIG. 14 is a cross-sectional view taken along a line II-II′ shown in FIG. 13. FIG. 15 is a cross-sectional view taken a long a line III-III′ shown in FIG. 13. It will be appreciated that the various features and advantages described above with respect to elements 10 and 20 of FIGS. 1 to 4 can be applied to elements 210 and 220, respectively, of FIGS. 13 to 15.

Referring to FIGS. 13 to 15, the TFT 300 includes a gate electrode 32, an insulating layer 45, a channel layer CL, a source electrode 55 and a drain electrode 57. The gate electrode 32 is electrically connected to a gate line 230. The source electrode 55 is electrically connected to a data line 50.

The gate line 230 is on a substrate 1. In this exemplary embodiment, a plurality of gate lines 230 are arranged substantially in parallel with one another. Each of the gate lines 230 extend in a first direction. The gate electrode 32 protrudes from the gate line 230.

In a display device having a resolution of 1024×764, the display device includes 764 gate lines. A turn-on signal or a turn-off signal is applied to the gate electrode 32 through the gate line 230. In this exemplary embodiment, 1024 gate electrodes 32 are electrically connected to each of the gate lines 230.

The gate line 230 includes a main wiring 210 and a sub-wiring 220. The main wiring 210 is on the substrate 1, and the sub-wiring 220 is on the main wiring 210. A pad member is formed on an end portion of the gate line 230. Alternatively, an auxiliary contact layer may be formed on the pad member.

The sub-wiring 220 that includes an alloy of the first metal has better contact characteristics with a transparent conductive layer than a sub-wiring that includes only one of the first and second metals.

In this exemplary embodiment, the sub-wiring 220 is etched with the main wiring 210 by the etchant so that sides of the main wiring 210 and the sub-wiring 220 are slanted relative to an upper surface of the substrate 1.

An insulating layer 45 on the substrate 1 covers the gate line 230.

The data line 50 is on the insulating layer 45. In this exemplary embodiment, a plurality of data lines 50 extend in a second direction that is substantially perpendicular to the first direction of the plurality of gate lines 230. A pad member is formed on an end portion of each of the data lines 50.

In a display device having a resolution of 1024×764, the display device includes 1024×3 data lines 50. An externally provided data signal is applied to the source electrode 55 through the data line 50. In this exemplary embodiment, 764 source electrodes 55 are electrically connected to each of the data lines 50.

The channel layer CL includes an amorphous silicon pattern ASP and two N⁺ amorphous silicon patterns nASP. The amorphous silicon pattern ASP is on the insulating layer 45 corresponding to the gate electrode 32. The N⁺ amorphous silicon patterns nASP are on the amorphous silicon pattern ASP.

The source electrode 55 and the drain electrode 57 are electrically connected to the N⁺ amorphous silicon patterns nASP, respectively. A pixel electrode PE is electrically connected to the drain electrode 57. The pixel electrode PE includes a transparent conductive material.

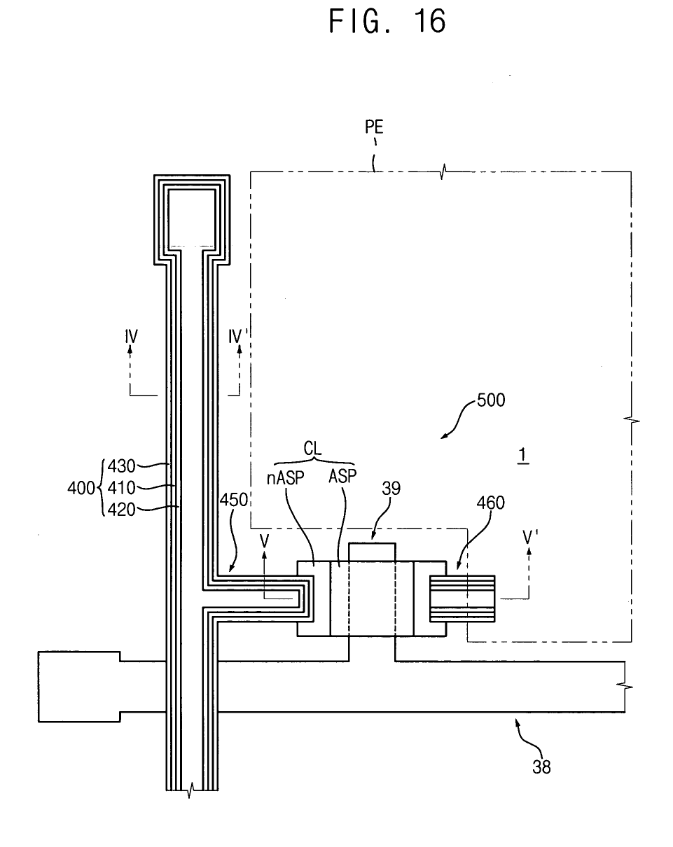

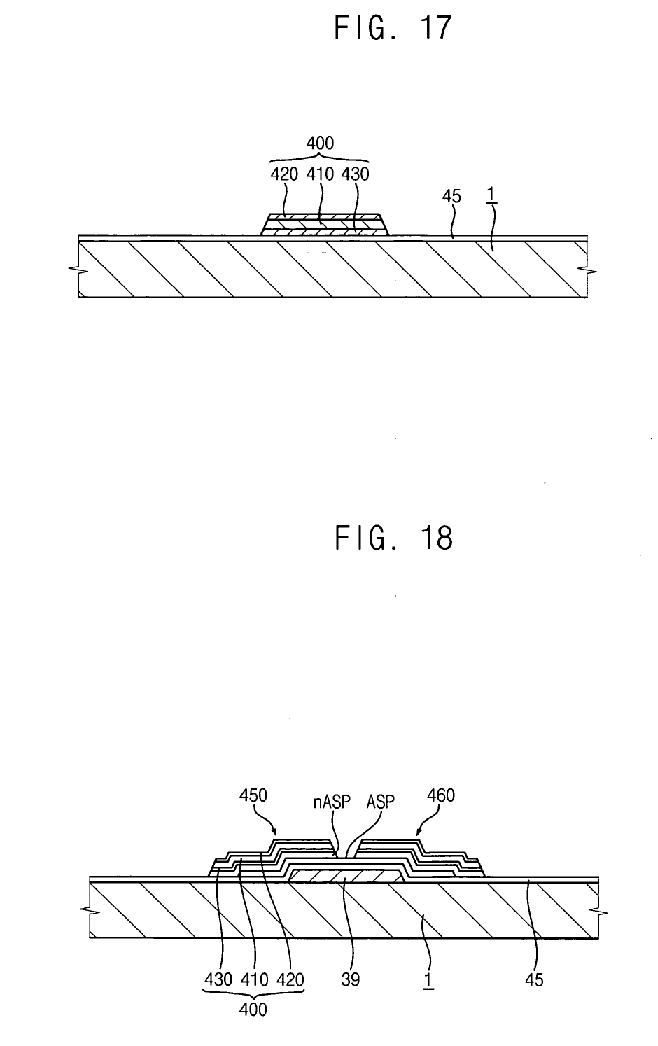

FIG. 16 is a plan view showing a TFT in accordance with another exemplary embodiment of the present invention. FIG. 17 is a cross-sectional view taken along a line IV-IV′ shown in FIG. 16. FIG. 18 is a cross-sectional view taken along a line V-V′ shown in FIG. 16. It will be appreciated that the various features and advantages described above with respect to elements 10 and 20 of FIGS. 1 to 4 can be applied to elements 410 and 420, respectively, of FIGS. 16 to 18. It will further be appreciated that the various features and advantages described above with respect to element 130 of FIG. 5 can be applied to element 430 of FIGS. 16 to 18. It will also be appreciated that the various features and advantages described above with respect to elements CL, ASP, and nASP of FIGS. 13 to 15 can be applied to elements CL, ASP, and nASP of FIGS. 16 to 18.

Referring to FIGS. 16 to 18, the TFT 500 includes a gate electrode 39, an insulating layer 45, a channel layer CLa, a source electrode 450 and a drain electrode 460. The gate electrode 39 is electrically connected to a gate line 38. The source electrode 450 is electrically connected to a data line 400.

The gate line 38 is on a substrate 1. In this exemplary embodiment, a plurality of gate lines 38 are arranged substantially in parallel with one another. Each of the gate lines 38 extend in a first direction. The gate electrode 39 protrudes from the gate line 38.

In a display device having a resolution of 1024×764, the display device includes 764 gate lines. A turn-on signal or a turn-off signal is applied to the gate electrode 39 through the gate line 38. In this exemplary embodiment, 1024 gate electrodes 39 are electrically connected to each of the gate lines 38.

An insulating layer 45 on the substrate 1 covers the gate line 38.

The data line 400 is on the insulating layer 45. In this exemplary embodiment, a plurality of data lines 400 extend in a second direction that is substantially perpendicular to the first direction of the plurality of gate lines 38. A pad member is formed on an end portion of each of the data lines 400.

In a display device having a resolution of 1024×764, the display device includes 1024×3 data lines 400. An externally provided data signal is applied to the source electrode 450 through the data line 400. In this exemplary embodiment, 764 source electrodes 450 are electrically connected to each of the data lines 400.

The data line 400 includes a main wiring 410, a sub-wiring 420 and an auxiliary sub-wiring 430. The main wiring 410 is on the insulating layer 45, and the sub-wiring 420 is on the main wiring 410. The auxiliary sub-wiring 430 is between the main wiring 410 and the insulating layer 45.

The auxiliary sub-wiring 430 is interposed between the insulating layer 45 and the main wiring 410.

It will be appreciated that embodiments of the present invention can provide a wiring that exhibits decreased electrical resistance and a reduced tendency to develop malfunctions such as hillocks or spiking. In addition, the wiring can exhibit improved contact characteristics with other conductive elements.

This invention has been described with reference to the exemplary embodiments set forth herein. It will be apparent to those having skill in the art that many alternative modifications and variations are possible in light of the foregoing description. The present invention embraces all such alternative modifications and variations as fall within the spirit and scope of the appended claims.

What is claimed is:

1. A multi-layer wiring comprising:
a main wiring comprising a first metal; and
a sub-wiring on the main wiring, the sub-wiring comprising an alloy, a majority of the alloy being the first metal.

2. The multi-layer wiring of claim 1, wherein the first metal comprises at least one selected from the group consisting of: aluminum, copper, and silver.

3. The multi-layer wiring of claim 1, wherein the alloy of the sub-wiring further comprises a second metal for preventing a deformation of the main wiring, and a third metal for improving contact characteristics of the multi-layer wiring.

4. The multi-layer wiring of claim 3, wherein the second metal comprises at least one selected from the group consisting of: neodymium, titanium, magnesium, silicon, molybdenum, and zirconium.

5. The multi-layer wiring of claim 3, wherein the third metal comprises at least one selected from the group consisting of: nickel, scandium, and zinc.

6. A multi-layer wiring comprising:
a main wiring comprising a first metal; and
a sub-wiring on a first surface of the main wiring, the sub-wiring comprising an alloy to dissipate a thermal stress of the main wiring so as to prevent a deformation of the main wiring and improve contact characteristics of the sub-wiring, a majority of the alloy being the first metal.

7. The multi-layer wiring of claim 6, wherein the first metal comprises at least one selected from the group consisting of: aluminum, copper, and silver.

8. The multi-layer wiring of claim 6, wherein the alloy of the sub-wiring further comprises a second metal for preventing the deformation of the first wiring, and a third metal for improving the contact characteristics of the multi-layer wiring.

9. The multi-layer wiring of claim 8, wherein the second metal comprises at least one selected from the group consisting of: neodymium, titanium, magnesium, silicon, molybdenum, and zirconium.

10. The multi-layer wiring of claim 9, wherein the alloy of the sub-wiring further comprises the second metal in a range of about 0.01 at % to about 5 at % with respect to the first metal.

11. The multi-layer wiring of claim 8, wherein the third metal comprises at least one selected from the group consisting of: nickel, scandium, and zinc.

12. The multi-layer wiring of claim 11, wherein the alloy of the sub-wiring further comprises the third metal in a range of about 0.01 at % to about 5 at % with respect to the first metal.

13. The multi-layer wiring of claim 6, wherein a thickness of the sub-wiring is in a range of about 10 Å to about 5,000 Å.

14. The multi-layer wiring of claim 6, further comprising a pad member on an end portion of the sub wiring, the pad member including an auxiliary contact layer.

15. The multi-layer wiring of claim 6, wherein sides of the main wiring and the sub-wiring are slanted relative to the first surface of the main wiring and the sub-wiring.

16. The multi-layer wiring of claim 6, further comprising an auxiliary sub-wiring on a second surface of the main wiring.

17. The multi-layer wiring of claim 16, wherein the auxiliary sub-wiring comprises at least one selected from the group consisting of: molybdenum, tungsten-molybdenum, neodymium-molybdenum, titanium-molybdenum, titanium, and tantalum, to prevent a diffusion of the first metal.

18. A multi-layer wiring comprising:
a main wiring comprising a first metal; and
a sub-wiring on a first surface of the main wiring, the sub-wiring comprising an alloy to dissipate a thermal stress of the main wiring, the alloy comprising a first metal, a second metal for preventing a deformation of the main wiring, and a third metal for improving contact characteristics.

19. The multi-layer wiring of claim 18, wherein the first metal comprises at least one selected from the group consisting of: aluminum, copper, and silver.

20. The multi-layer wiring of claim 18, wherein the second metal comprises at least one selected from the group consisting of: neodymium, titanium, magnesium, silicon, molybdenum, and zirconium.

21. The multi-layer wiring of claim 20, wherein the alloy of the sub-wiring further comprises the second metal in a range of about 0.01 at % to about 5 at % with respect to the first metal.

22. The multi-layer wiring of claim 20, wherein the third metal comprises at least one selected from the group consisting of: nickel, scandium, and zinc.

23. The multi-layer wiring of claim 22, wherein the alloy of the sub-wiring further comprises the third metal in a range of about 0.01 at % to about 5 at % with respect to the first metal.

24. The multi-layer wiring of claim 18, further comprising an auxiliary sub-wiring on a second surface of the main wiring.

25. The multi-layer wiring of claim 24, wherein the auxiliary sub-wiring comprises at least one selected from the group consisting of: molybdenum, tungsten-molybdenum, neodymium-molybdenum, titanium-molybdenum, titanium, and tantalum, to prevent a diffusion of the first metal.

26. A multi-layer wiring comprising:
a main wiring including a first metal, the first metal comprising at least one selected from the group consisting of: aluminum, copper, and silver; and
a sub-wiring on a first surface of the main wiring, the sub-wiring comprising an alloy to dissipate a thermal stress of the main wiring, the alloy comprising the first metal, a second metal for preventing a deformation of the main wiring, and a third metal for improving contact characteristics, the second metal comprising at least one selected from the group consisting of: neodymium, titanium, magnesium, silicon, molybdenum, and zirconium, the third metal comprising at least one selected from the group consisting of: nickel, scandium, and zinc.

27. The multi-layer wiring of claim 26, further comprising an auxiliary sub-wiring on a second surface of the main wiring.

28. The multi-layer wiring of claim 27, wherein the auxiliary sub-wiring comprises at least one selected from the group consisting of: molybdenum, tungsten-molybdenum, neodymium-molybdenum, titanium-molybdenum, titanium, and tantalum, to prevent a diffusion of the first metal.

29. A method of manufacturing a multi-layer wiring comprising:
forming a main thin film on a substrate, the main thin film comprising a first metal;
forming a sub-thin film on an upper surface of the main thin film, the sub-thin film comprising an alloy to dissipate a thermal stress of the main thin film so as to prevent a deformation of the main thin film and improve contact characteristics, a majority of the alloy being the first metal; and
partially etching the sub-thin film and the main thin film to form a main wiring on the substrate and a sub-wiring on the main wiring.

30. The method of claim 29, wherein the first metal comprises at least one selected from the group consisting of: aluminum, copper, and silver.

31. The method of claim 29, wherein the alloy of the sub-thin film further comprises a second metal for preventing the deformation of the main thin film, and a third metal for improving contact characteristics of the multi-layer wiring.

32. The method of claim 31, wherein the second metal comprises at least one selected from the group consisting of: neodymium, titanium, magnesium, silicon, molybdenum, and zirconium.

33. The method of claim 32, wherein the alloy of the sub-wiring comprises the second metal in a range of about 0.01 at % to about 5 at % with respect to the first metal.

34. The method of claim 31, wherein the third metal comprises at least one selected from the group consisting of: nickel, scandium, and zinc.

35. The method of claim 34, wherein the alloy of the sub-wiring comprises the third metal in a range of about 0.01 at % to about 5 at % with respect to the first metal.

36. The method of claim 29, wherein a thickness of the sub-wiring is in a range of about 10 Å to about 5,000 Å.

37. The method of claim 29, wherein each of the main thin film and the sub-thin film is formed by a method comprising at least one selected from the group consisting of: a chemical vapor deposition (CVD) method and a sputtering method.

38. The method of claim 29, further comprising:
prior to the forming of the main thin film, forming an auxiliary sub-thin film on the substrate.

39. The method of claim 38, wherein the auxiliary sub-thin film comprises at least one selected from the group consisting of: molybdenum, tungsten-molybdenum, neodymium-molybdenum, titanium-molybdenum, titanium. and tantalum, to prevent a diffusion of the first metal.

40. A thin film transistor comprising:
a gate line on a substrate, the gate line being electrically connected to a gate electrode, the gate line including:
a main wiring comprising a first metal; and
a sub-wiring on a first surface of the main wiring, the sub-wiring comprising an alloy to dissipate a thermal stress of the main wiring so as to prevent a deformation of the main wiring and improve contact characteristics, a majority of the alloy being the first metal;
an insulating layer on the substrate having the gate line and the gate electrode;
a channel layer on a portion of the insulating layer corresponding to the gate electrode;
a data line substantially perpendicular to the gate line on the insulating layer, the data line being electrically connected to a source electrode that is electrically connected to the channel layer; and
a drain electrode electrically connected to the channel layer.

41. The thin film transistor of claim 40, wherein the first metal comprises at least one selected from the group consisting of: aluminum, copper, and silver.

42. The thin film transistor of claim 40, wherein the alloy of the sub-wiring further comprises a second metal for preventing a deformation of the main wiring, and a third metal for improving contact characteristics of the main wiring.

43. The thin film transistor of claim 42, wherein the second metal comprises at least one selected from the group consisting of: neodymium, titanium, magnesium, silicon, molybdenum, and zirconium.

44. The thin film transistor of claim 43, wherein the alloy of the sub-wiring comprises the second metal in a range of about 0.01 at % to about 5 at % with respect to the first metal.

45. The thin film transistor of claim 42, wherein the third metal comprises at least one selected from the group consisting of: nickel, scandium, and zinc.

46. The thin film transistor of claim 45, wherein the alloy of the sub-wiring comprises the third metal in a range of about 0.01 at % to about 5 at % with respect to the first metal.

47. A thin film transistor comprising:
a gate line on a substrate, the gate line being electrically connected to a gate electrode;
an insulating layer on the substrate having the gate line and the gate electrode;
a channel layer on the gate insulating layer corresponding to the gate electrode;
a data line substantially perpendicular to the gate line on the insulating layer, the data line being electrically connected to a source electrode that is electrically connected to the channel layer, the data line including:
a main wiring comprising the first metal;
a sub-wiring on a first surface of the main wiring, the sub-wiring comprising an alloy to dissipate a thermal stress of the main wiring so as to prevent a deformation of the main wiring and improve contact characteristics, a majority of the alloy being the first metal; and
an auxiliary sub-wiring on a second surface of the main wiring to prevent a diffusion of the first metal; and
a drain electrode electrically connected to the channel layer.
